(19) United States
(12) Patent Application Publication
(10) Pub. No.: US 2026/0245635 A1
(43) Pub. Date: Aug. 20, 2026

(54) APPARATUS AND METHOD FOR PERFORMING A READ OPERATION IN A MEMORY DEVICE

(71) Applicant: SK hynix Inc., Gyeonggi-do (KR)

(72) Inventors: Yeong Jo MUN, Gyeonggi-do (KR); Duck Ju KIM, Gyeonggi-do (KR); Se Chun PARK, Gyeonggi-do (KR)

(21) Appl. No.: 19/253,996

(22) Filed: Jun. 30, 2025

(30) Foreign Application Priority Data
Feb. 18, 2025 (KR) 10-2025-0020650

(51) Int. Cl. G11C 16/30; G11C 16/04; G11C 16/24; G11C 16/26

(52) U.S. Cl. CPC G11C 16/30; G11C 16/0483; G11C 16/24; G11C 16/26

(57) ABSTRACT

A memory device includes at least one memory cell configured to store at least one bit of data, at least one page buffer configured to store data read from the at least one memory cell, and a current mirror arranged between the at least one memory cell and the at least one page buffer, the current mirror having a current gain which is adaptively adjustable or controllable.

### CROSS-REFERENCE TO RELATED APPLICATIONS

This patent application claims the benefit of Korean Patent Application No. 10-2025-0020650, filed on Feb. 18, 2025, the entire disclosure of which is incorporated herein by reference.

### TECHNICAL FIELD

Embodiments of the present disclosure described herein relate to a memory system, and more particularly, to an apparatus and a method for performing a read operation in a memory device.

### BACKGROUND

A data processing system includes a memory system or a data storage device. The data processing system can be developed to store more voluminous data in the data storage device, store data in the data storage device faster, and read data stored in the data storage device faster. The memory system or the data storage device can include non-volatile memory cells and/or volatile memory cells for storing data. In order to improve operational safety of an internal operation associated with a command transmitted from an external device, the memory system can control an operation for reading data stored in the memory cells.

### BRIEF DESCRIPTION OF THE DRAWINGS

The description herein makes reference to the accompanying drawings wherein like reference numerals refer to like parts throughout the figures.

FIG. 1 illustrates the structure and operation of a memory device according to an embodiment of the present disclosure.

FIG. 2 illustrates a memory system according to an embodiment of the present disclosure.

FIG. 3 illustrates a memory device according to an embodiment of the present disclosure.

FIG. 4 illustrates a structure of a first cell array in a memory device, according to an embodiment of the present disclosure.

FIG. 5 illustrates a structure of a second cell array in a memory device, according to an embodiment of the present disclosure.

FIG. 6 illustrates a structure of a third cell array in a memory device, according to an embodiment of the present disclosure.

FIG. 7 illustrates a memory device according to an embodiment of the present disclosure.

FIG. 8 illustrates a memory device according to an embodiment of the present disclosure.

FIG. 9 illustrates a memory device according to an embodiment of the present disclosure.

FIG. 10 illustrates a memory device according to an embodiment of the present disclosure.

FIG. 11 illustrates a memory device according to an embodiment of the present disclosure.

FIG. 12 illustrates an operation of the memory device described in FIG. 11, according to an embodiment of the present disclosure.

### DETAILED DESCRIPTION

Various embodiments of the present disclosure are described below with reference to the accompanying drawings. Elements and features of this disclosure may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. Furthermore, the terms in a claim do not foreclose the apparatus from including additional components, e.g., an interface unit, circuitry, etc.

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational, e.g., is not turned on nor activated. The block/unit/circuit/component used with the “configured to” language may include hardware, for example, circuits, memory storing program instructions executable to implement the operation, etc. Additionally, “configured to” can include a generic structure (e.g., generic circuitry) that is manipulated by software and/or firmware (e.g., an FPGA or a general-purpose processor executing software) to operate in a manner capable of performing the task(s) at issue. “Configured to” may also include adapting a manufacturing process (e.g., a semiconductor fabrication facility) to fabricate devices (e.g., integrated circuits) that are adapted to implement or perform one or more tasks.

As used in this disclosure, the term ‘circuitry’ or ‘logic’ refers to all of the following: (a) hardware-only circuit implementations (such as implementations in only analog and/or digital circuitry) and (b) combinations of circuits and software (and/or firmware), such as (as applicable): (i) to a combination of processor(s) or (ii) to portions of processor(s)/software (including digital signal processor(s)), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of ‘circuitry’ or ‘logic’ applies to all uses of this term in this application, including in any claims. As a further example, as used in this application, the term “circuitry” or “logic” also covers an implementation of merely a processor (or multiple processors) or portion of a processor and its (or their) accompanying software and/or firmware. The term “circuitry” or “logic” also covers, for example, and if applicable to a particular claim element, an integrated circuit for a storage device.

As used herein, the terms “first,” “second,” “third,” and so on are used as labels for nouns that they precede, and do not imply any type of ordering (e.g., spatial, temporal, logical, etc.). The terms “first” and “second” do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term “based on” is used to describe one or more factors that affect a determination. This term does not foreclose additional factors that may affect a determination. That is, a determination may be solely based on those factors or based, at least in part, on those factors. Consider the phrase “determine A based on B.” While in this case, B is a factor that affects the determination of A, such a phrase does not foreclose the determination of A from also being based on C. In other instances, A may be determined based solely on B.

Herein, a data entry, an entry of data, an item of data, or a data item may be a sequence of bits. For example, the data entry may include the contents of a file, a portion of the file, a page in memory, an object in an object-oriented program, a digital message, a digital scanned image, a part of a video or audio signal, metadata or any other entity which can be represented by a sequence of bits. According to an embodiment, the data entry may include a discrete object. According to another embodiment, the data entry may include a unit of information processed or handled for a data input/output operation. According to another embodiment, the data entry may include a unit of information within a transmission packet between two different components.

Embodiments in the present disclosure can provide a memory system, a data processing system, and an operation process or a method, which may quickly and reliably process data into a memory device by reducing operational complexity and performance degradation of the memory system, thereby enhancing usage efficiency of the memory device.

Embodiments of the present disclosure may solve an issue that an amount of current flowing through a bit line corresponding to data stored in a memory cell decreases in a three-dimensional high-density memory device, making it difficult to detect or sense the data, by arranging a current mirror between a bit line and a sense line and allowing an increased current to flow through the sense line for a limited time range, the increase current being greater than the current flowing in the bit line, thereby improving operating characteristics of the memory device.

In addition, because an embodiment of the present disclosure can increase an amount of the current through the current mirror even if a current flowing in the bit line coupled to the memory cell is small, power consumption of the memory device may be reduced and the memory device may operate even in a low-power environment.

Further, an embodiment of the present disclosure is a memory device including a current mirror for increasing an amount of the current flowing, in response to data stored in a non-volatile memory cell, through a bit line coupled to the non-volatile memory cell and transmitting the increased current to a page buffer, so that a reduction in the amount of the current flowing through the non-volatile memory cell in the memory device formed with a plurality of stacks may be overcome without an improvement in the design or fabricating process, thereby improving production efficiency and production cost.

In an embodiment, a memory device may include at least one memory cell configured to store at least one bit of data; at least one page buffer configured to store data read from the at least one memory cell; and a current mirror arranged between the at least one memory cell and the at least one page buffer, the current mirror having a current gain which is adaptively adjustable or controllable.

The memory device may further include a word line connected to the at least one memory cell; a bit line connected to the at least one memory cell; and a sensing line connected to the at least one page buffer. The current mirror may connect the bit line to the sensing line. The current gain may be greater than 1.

In the memory device, an operation for reading data stored in the at least one memory cell may include a precharge period, an evaluation period, and a sensing period. The current mirror may be configured to generate, during the evaluation period, an amount of a second current flowing through the sensing line greater than an amount of a first current flowing through the bit line.

The at least one memory cell may be configured to store multi-bit data. The first current flowing through the at least one memory cell and the bit line may be determined in response to one of plural levels of a read voltage supplied through the word line.

The at least one page buffer may be configured to store a binary value that is determined based whether the second current is detected.

The current gain of the current mirror may have different values during a read operation and a program operation. A connection time between the at least one memory cell and the at least one page buffer may vary during the read operation and the program operation.

The current gain of the current mirror may be determined during a test process performed after manufacturing of the memory device.

The current gain of the current mirror may vary depending on a wear degree of the at least one memory cell.

The current mirror may include P-channel metal-oxide-semiconductor (PMOS) transistors each having one side connected to a power supply voltage.

The current mirror may include N-channel metal-oxide-semiconductor (NMOS) transistors each having one side connected to a ground voltage.

The current mirror may include inductors each having one side connected to a power supply voltage.

In another embodiment, a non-volatile memory device may include a cell string including a plurality of memory cells connected in series; a bit line connected to the cell string; a current mirror connected to the bit line; and at least one page buffer connected to the current mirror.

In the non-volatile memory device, an amount of current flowing through the cell string and the bit line may be determined when voltages of different levels are applied through a plurality of word lines respectively connected to each of the plurality of memory cells. The current mirror may be configured to increase the current by N times, and flow the increased current to the at least one page buffer, N being a positive number greater than 1.

The at least one page buffer may be configured to store a binary value that is determined based on whether the increased current output from the current mirror is detected.

The current mirror may include PMOS transistors each having one side connected to a power supply voltage.

The current mirror may include NMOS transistors each having one side connected to a ground voltage.

The current mirror may include inductors each having one side connected to a power supply voltage.

The bit line and the at least one page buffer may be not directly electrically connected.

In another embodiment, a method for operating a memory device may include applying a read voltage to a word line connected to a memory cell; precharging a sensing line connected to a page buffer; operating a current mirror to increase an amount of a current, flowing through a bit line connected to the memory cell, by N times and flow the increased current to the precharged sensing line, N being a positive number greater than 1; and storing, in the page buffer, a binary value that is determined based on whether the current flowed to the sensing line by from the current mirror is detected.

The binary value may be stored in the page buffer after the current mirror is disconnected from the sensing line.

An embodiment described herein can provide an apparatus and a method for improving a data input/output operation of a memory system or a data processing system.

Embodiments will now be described with reference to the accompanying drawings, wherein like numbers reference like elements.

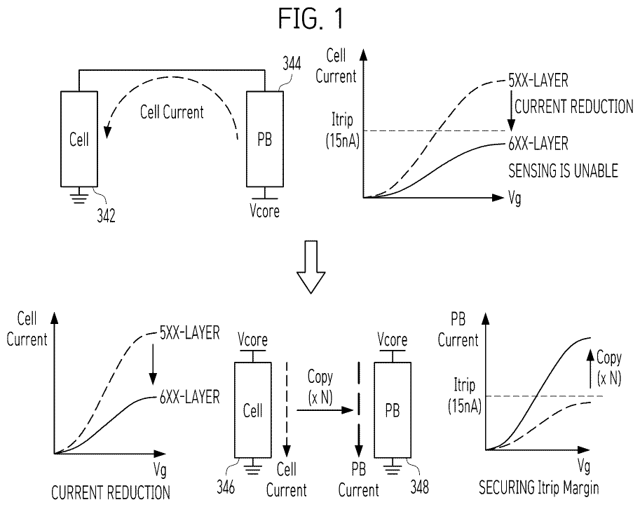

FIG. 1 illustrates the structure and operation of a memory device according to an embodiment of the present disclosure.

Referring to FIG. 1, a conventional memory device can include a memory cell (cell) 342 and a page buffer (PB) 344. The memory cell 342 and the page buffer 344 may be electrically directly connected. In this context, being directly connected means that a current path is connected through which a current flowing through the memory cell 342 can flow to the page buffer 344. A power voltage (Vcore) may be connected to the page buffer 344, and a ground voltage may be connected to the memory cell 342. The current path can be formed to pass through the page buffer 344 and the memory cell 342 between the power voltage (Vcore) and the ground voltage. The page buffer 344 may store a binary value in response to whether or not a cell current flowing through the memory cell 342 is detected (e.g., store a value dependent on whether a cell current is detected).

A memory device may be formed with a plurality of memory cells, and the plurality of memory cells may be formed as a three-dimensional structure. In a three-dimensional structure in which dozens or more layers/dies are stacked, each layer/die including the plurality of memory cells arranged in an array form, the cell current may decrease as the number of layers/dies in the stack increases. Therefore, in a first stack 5XX-LAYER, the cell current may be greater than an amount of cell current (Itrip), for example, 15 nA, which may be detectable by the page buffer 344, so that it may not be difficult for the page buffer 344 to detect the cell current. However, in a second stack 6XX-LAYER, the cell current may be not greater than the amount of cell current (Itrip), for example, 15 nA, which can be detectable by the page buffer 344, so that it may be difficult for the page buffer 344 to detect the cell current. The page buffer 344 could not sense or detect the cell current when the cell current is too small (e.g., less than 15 nA). For this reason, a margin of the read operation performed in the memory device having the second stack might be lengthened, and an additional operation may be required to increase the amount of cell current in the second stack. The sensing as configured may be unable to detect the cell current.

Further, a memory device according to an embodiment of the present disclosure may include a memory cell (cell) 346 and a page buffer (PB) 348. The memory cell 346 and the page buffer 348 may be structurally identical to the memory cell 342 and the page buffer 344. However, the memory cell 346 and the page buffer 348 in the memory device may not be directly connected through a single current path. Different current paths are formed individually through the memory cell 346 and the page buffer 348. The memory device may copy a current flowing through the memory cell 346 to be N (where N is a positive number greater than 1) times larger and cause N times current to flow through the page buffer 344. That is, a page buffer current (e.g., PB Current) N times the cell current (e.g., Cell current) flowing through the memory cell 346 may flow through the page buffer 344.

In the case of the first stack 5XX-LAYER in the three-dimensional structure of the conventional memory device, the amount of cell current may be sufficient, but the amount of cell current may be not sufficient in the second stack 6XX-LAYER. On the other hand, in the memory device according to one embodiment of the present disclosure, the page buffer current (e.g., PB Current) that increases the cell current by N times can flow through the page buffer 348 in the second stack 6XX-LAYER. Through this scheme, a detection margin (e.g., Itrip sensing margin) may be secured through the page buffer current (e.g., PB Current) corresponding to the cell current in the second stack 6XX-LAYER because the page buffer current may be detected (is detectable) by the page buffer 348.

Meanwhile, the page buffer 348 can detect the page buffer current (e.g., PB Current) that increases the cell current, flowing through the memory cell 346, by N times, faster than detecting the cell current, because the page buffer current has a greater amount than the cell current. Accordingly, the margin for the read operation of the memory device may be reduced, and the data input/output performance of the memory device could be improved.

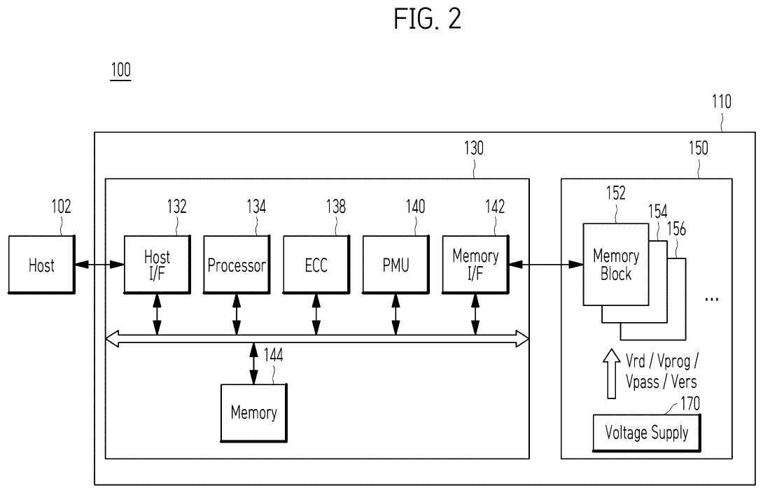

FIG. 2 illustrates a memory system according to an embodiment of the present disclosure.

Referring to FIG. 2, the data processing system 100 may include a host 102 engaged or coupled with a memory system, such as memory system 110. For example, the host 102 and the memory system 110 may be coupled to each other via a data bus, a host cable, and the like, to perform data communication.

The memory system 110 may include a memory device 150 and a controller 130. The memory device 150 and the controller 130 in the memory system 110 may be considered components or elements physically separated from each other. The memory device 150 and the controller 130 may be connected via at least one data path. For example, the data path may include a channel and/or a way.

According to an embodiment, the memory device 150 and the controller 130 may be components or elements functionally divided. Further, according to an embodiment, the memory device 150 and the controller 130 may be implemented with a single chip or a plurality of chips. The controller 130 may perform a data input/output operation in response to a request input from the external device. For example, when the controller 130 performs a read operation in response to a read request input from an external device, data stored in a plurality of non-volatile memory cells included in the memory device 150 is transferred to the controller 130.

As shown in FIG. 2, the memory device 150 may include a plurality of memory blocks 152, 154, 156. The memory blocks 152, 154, 156 may be understood as a group of non-volatile memory cells in which data is removed together by a single erase operation. Although not illustrated, the memory block 152, 154, 156 may include a page which is a group of non-volatile memory cells that store data together during a single program operation or output data together during a single read operation. For example, one memory block may include a plurality of pages.

For example, the memory device 150 may include a plurality of memory planes or a plurality of memory dies. According to an embodiment, the memory plane may be considered a logical or a physical partition including at least one memory block, a driving circuit capable of controlling an array including a plurality of non-volatile memory cells, and a buffer that can temporarily store data input to, or output from, non-volatile memory cells.

In addition, according to an embodiment, the memory die may include at least one memory plane. The memory die may be understood to be a set of components implemented on a physically distinguishable substrate. Each memory die may be connected to the controller 130 through a data path. Each memory die may include an interface to exchange an item of data and a signal with the controller 130.

According to an embodiment, the memory device 150 may include at least one memory block 152, 154, 156, at least one memory plane, or at least one memory die. The internal configuration of the memory device 150 shown in FIGS. 1 and 2 may be different according to the configuration, performance, and/or design of the memory system 110. An embodiment of the present disclosure is not limited to the internal configuration shown in FIG. 2.

Referring to FIG. 2, the memory device 150 may include a voltage supply circuit 170 capable of supplying at least some voltage into the memory block 152, 154, 156. The voltage supply circuit 170 may supply a read voltage Vrd, a program voltage Vprog, a pass voltage Vpass, or an erase voltage Vers into a non-volatile memory cell included in the memory block. For example, during a read operation for reading data stored in the non-volatile memory cell included in the memory block 152, 154, 156, the voltage supply circuit 170 may supply the read voltage Vrd into a selected non-volatile memory cell. During the program operation for storing data in the non-volatile memory cell included in the memory block 152, 154, 156, the voltage supply circuit 170 may supply the program voltage Vprog into a selected non-volatile memory cell. Also, during a read operation or a program operation performed on the selected nonvolatile memory cell, the voltage supply circuit 170 may supply a pass voltage Vpass into a non-selected nonvolatile memory cell. During the erasing operation for erasing data stored in the non-volatile memory cell included in the memory block 152, 154, 156, the voltage supply circuit 170 may supply the erase voltage Vers into the memory block.

The memory device 150 may store information regarding various voltages which are supplied to the memory block 152, 154, 156 based on which operation is performed. For example, when a non-volatile memory cell in the memory block 152, 154, 156 can store multi-bit data, plural levels of the read voltage Vrd for recognizing or reading the multi-bit data entry may be required. The memory device 150 may include a table including information corresponding to plural levels of the read voltage Vrd, corresponding to the multi-bit data entry. For example, the table may include bias values stored in a register, each bias value corresponding to a specific level of the read voltage Vrd. The number of bias values for the read voltage Vrd that is used for a read operation may be limited to a preset range. Also, the bias values may be quantified (or quantized).

The host 102 may include a portable electronic device, e.g., a mobile phone, an MP3 player, a laptop computer, etc., or a non-portable electronic device, e.g., a desktop computer, a game player, a television, a projector, etc.

The host 102 may also include at least one operating system (OS), which may control functions and operations performed in the host 102. The OS may provide interoperability between the host 102 engaged operatively with the memory system 110 and a user who intends to store data in the memory system 110. The OS may support functions and operations corresponding to user's requests. By way of example but not limitation, the OS may be classified into a general operating system and a mobile operating system according to mobility of the host 102. The general operating system may be further classified into a personal operating system and an enterprise operating system according to system requirements or a user environment. As compared with the personal operating system, the enterprise operating systems can be specialized for securing and supporting high performance computing.

The mobile operating system may be subject to support services or functions for mobility, e.g., a power saving function. The host 102 may include a plurality of operating systems. The host 102 may execute multiple operating systems interlocked with the memory system 110, corresponding to a user's request. The host 102 may transmit a plurality of commands corresponding to the user's requests into the memory system 110, thereby performing operations corresponding to the plurality of commands within the memory system 110.

A controller 130 in the memory system 110 may control a memory device 150 in response to a request or a command input from the host 102. For example, the controller 130 may perform a read operation to provide data read from the memory device 150 to the host 102 and may perform a write operation (or a program operation) to store data input from the host 102 in the memory device 150. In order to perform data input/output (I/O) operations, the controller 130 may control and manage internal operations of reading data, programming data, erasing data, or the like.

According to an embodiment, the controller 130 may include a host interface 132, a processor 134, an error correction circuitry (ECC) 138, a power management unit (PMU) 140, a memory interface (I/F) 142, and a memory 144. Components included in the controller 130 as illustrated in FIG. 2 may vary according to structures, functions, operation performance, or the like, implemented in (or associated with, configured for) the memory system 110.

For example, the memory system 110 may be implemented with any of various types of storage devices, which may be electrically coupled with the host 102, according to a protocol of a host interface. Non-limiting examples of suitable storage devices include a solid state drive (SSD), a multimedia card (MMC), an embedded MMC (eMMC), a reduced size MMC (RS-MMC), a micro-MMC, a secure digital (SD) card, a mini-SD, a micro-SD, a universal serial bus (USB) storage device, a universal flash storage (UFS) device, a compact flash (CF) card, a smart media (SM) card, a memory stick, and the like. Components may be added to or omitted from the controller 130 according to implementation of the memory system 110.

The host 102 and the memory system 110 each may include a controller or an interface for transmitting and receiving signals, data, and the like, in accordance with one or more predetermined protocols. For example, the host interface 132 in the memory system 110 may include an apparatus capable of transmitting signals, data, and the like to the host 102 or receiving signals, data, and the like from the host 102.

The host interface 132 included in the controller 130 may receive signals, commands (or requests), and/or data input from the host 102 via a bus. For example, the host 102 and the memory system 110 may use a predetermined set of rules or procedures for data communication or a preset interface to transmit and receive data therebetween. Examples of sets of rules or procedures for data communication standards or interfaces supported by the host 102 and the memory system 110 for sending and receiving data include Universal Serial Bus (USB), Multi-Media Card (MMC), Parallel Advanced Technology Attachment (PATA), Small Computer System Interface (SCSI), Enhanced Small Disk Interface (ESDI), Integrated Drive Electronics (IDE), Peripheral Component Interconnect Express (PCIe or PCI-e), Serial-attached SCSI (SAS), Serial Advanced Technology Attachment (SATA), Mobile Industry Processor Interface (MIPI), and the like. According to an embodiment, the host interface 132 may be a type of layer for exchanging data with the host 102 and may be implemented with, or driven by, firmware such as a host interface layer (HIL). According to an embodiment, the host interface 132 may include a command queue.

An Integrated Drive Electronics (IDE) interface or an Advanced Technology Attachment (ATA) interface may be used as one of the interfaces for transmitting and receiving data and, for example, may use a cable including 40 wires connected in parallel to support data transmission and data reception between the host 102 and the memory system 110. When a plurality of memory systems 110 are connected to a single host 102, the plurality of memory systems 110 may be divided into a master and a slave by using a position or a dip switch to which the plurality of memory systems 110 are connected. The memory system 110 set as the master may be used as a main memory device. The IDE (ATA) may include, for example, Fast-ATA, ATAPI, or Enhanced IDE (EIDE).

A Serial Advanced Technology Attachment (SATA) interface is a type of serial data communication interface that is compatible with various ATA standards of parallel data communication interfaces which are used by Integrated Drive Electronics (IDE) devices. The 40 wires in the IDE interface can be reduced to six wires in the SATA interface. For example, 40 parallel signals for the IDE may be converted into 6 serial signals for the SATA interface. The SATA interface has been widely used because of its faster data transmission and reception rate and its less resource consumption in the host 102 used for data transmission and reception. The SATA interface may connect up to 30 external devices to a single transceiver included in the host 102. In addition, the SATA interface may support hot plugging that allows an external device to be attached to or detached from the host 102, even while data communication between the host 102 and another device is being executed. Thus, the memory system 110 can be connected or disconnected as an additional device, like a device supported by a universal serial bus (USB) even when the host 102 is powered on. For example, in the host 102 having an eSATA port, the memory system 110 may be freely attached to or detached from the host 102 in the manner of (attaching and detaching) an external hard disk.

Small Computer System Interface (SCSI) is a type of serial data communication interface used for connecting a computer or a server with other peripheral devices. The SCSI can provide a high transmission speed, as compared with other interfaces such as IDE and SATA. In (combined) systems that implement SCSI, the host 102 and at least one peripheral device (e.g., memory system 110) are connected in series, but data transmission and reception between the host 102 and each peripheral device may be performed through parallel data communication (or a parallel data connection). In the systems that implement SCSI, devices such as the memory system 110 may be easily (for example, with stability and/or minimal processing or adjustment required) connected to or disconnected from the host 102. The SCSI can support connections of 15 other devices to a single transceiver included in host 102.

Serial Attached SCSI (SAS) may be understood to be a serial data communication version of the SCSI. In the SAS, the host 102 and a plurality of peripheral devices are connected in series, and data transmission and reception between the host 102 and each peripheral device may be performed (or executed) in a serial data communication scheme. The SAS may support connection between the host 102 and the peripheral device through a serial cable instead of a parallel cable, to easily (for example, in a timely manner without additional processes, protocol or devices, etc.) manage equipment using the SAS and enhance or improve operational reliability and communication performance. The SAS may support connections of eight external devices to a single transceiver included in the host 102.

The Non-volatile memory express (NVMe) is a type of interface based at least on a Peripheral Component Interconnect Express (PCIe) designed to increase performance and design flexibility of the host 102, servers, computing devices, and the like equipped with the non-volatile memory system 110. The PCIe may use a slot or a specific cable for connecting a computing device (e.g., host 102) and a peripheral device (e.g., memory system 110). For example, the PCIe may use a plurality of pins (e.g., 18 pins, 32 pins, 49 pins, or 82 pins) and at least one wire (e.g., x1, x4, x8, or x16) to achieve high speed data communication over several hundred MB per second (e.g., 250 MB/s, 500 MB/s, 984.6250 MB/s, or 1969 MB/s). According to an embodiment, the PCIe scheme may achieve bandwidths of tens to hundreds of Giga bits per second. The NVMe may support an operation speed of the non-volatile memory system 110, such as an SSD, that is faster than a hard disk.

According to an embodiment, the host 102 and the memory system 110 may be connected through a universal serial bus (USB). The Universal Serial Bus (USB) is a type of scalable, hot-pluggable plug-and-play serial interface that can provide cost-effective standard connectivity between the host 102 and peripheral devices such as a keyboard, a mouse, a joystick, a printer, a scanner, a storage device, a modem, a video camera, and the like. A plurality of peripheral devices such as the memory system 110 may be coupled to a single transceiver included in the host 102.

Referring to FIG. 2, the error correction circuitry 138 may correct error bits of data read from the memory device 150, and may include an error correction code (ECC) encoder and an ECC decoder. The ECC encoder may perform error correction encoding of data to be programmed in the memory device 150 to generate encoded data into which a parity bit is added, and store the encoded data in the memory device 150. The ECC decoder may detect and correct error bits contained in the data read from the memory device 150 when the controller 130 reads the data stored in the memory device 150. For example, after performing error correction decoding on the data read from the memory device 150, the error correction circuitry 138 determines whether the error correction decoding has succeeded or not, and outputs an instruction signal, e.g., a correction success signal or a correction fail signal, based on a result of the error correction decoding. The error correction circuitry 138 may use a parity bit, which has been generated during the ECC encoding process for the data stored in the memory device 150, in order to correct the error bits of the read data entries. When the number of the error bits is greater than or equal to the number of correctable error bits, the error correction circuitry 138 may not correct the error bits and may instead output the correction fail signal indicating a failure in correcting the error bits.

According to an embodiment, the error correction circuitry 138 may perform an error correction operation based on a coded modulation such as a low density parity check (LDPC) code, a Bose-Chaudhuri-Hocquenghem (BCH) code, a turbo code, a Reed-Solomon (RS) code, a convolution code, a recursive systematic code (RSC), a trellis-coded modulation (TCM), a Block coded modulation (BCM), or the like. The error correction circuitry 138 may include all circuits, modules, systems, and/or devices for performing the error correction operation based on at least one of the above-described codes.

For example, the ECC decoder may perform hard decision decoding or soft decision decoding on data transmitted from the memory device 150. The hard decision decoding can be understood as one of two methods broadly classified for error correction. The hard decision decoding may include an operation of correcting an error bit by reading digital data of ‘0’ or ‘1’ from a non-volatile memory cell in the memory device 150. Because the hard decision decoding handles a binary logic signal, the circuit/algorithm design or configuration may be simpler than the soft decision decoding, and a processing speed may be faster than the soft decision decoding.

The soft decision decoding may quantize a threshold voltage of a non-volatile memory cell in the memory device 150 by two or more quantized values, e.g., multiple bit data, approximate values, an analog value, and the like, in order to correct an error bit based on the two or more quantized values. The controller 130 may receive two or more alphabets or quantized values from a plurality of non-volatile memory cells in the memory device 150, and then perform a decoding based on information generated by characterizing the quantized values as a combination of information such as conditional probability or likelihood.

According to an embodiment, the ECC decoder may use a low-density parity-check and generator matrix (LDPC-GM) code among methods designed for the soft decision decoding. The low-density parity-check (LDPC) code uses an algorithm that can read values of data from the memory device 150 in several bits according to reliability, not simply data of 1 or 0 in the manner of the hard decision decoding, and iteratively repeats the process through a message exchange in order to improve reliability of the values. Then, the values are finally determined as data of 1 or 0. For example, a decoding algorithm using LDPC codes can be understood as probabilistic decoding. In the hard decision decoding, a value output from a non-volatile memory cell may be decoded as 0 or 1. Compared to the hard decision decoding, the soft decision decoding can determine the value stored in the non-volatile memory cell based on the stochastic information. Regarding bit-flipping which may be considered an error that can occur in the memory device 150, the soft decision decoding may provide improved probability of correcting the error and recovering data, as well as providing reliability and stability of corrected data. The LDPC-GM code may have a scheme in which internal LDGM codes can be concatenated in series with high-speed LDPC codes.

According to an embodiment, the ECC decoder may use, for example, low-density parity-check convolutional codes (LDPC-CCs) for the soft decision decoding. The LDPC-CCs may have a scheme using a linear time encoding and a pipeline decoding based on a variable block length and a shift register.

According to an embodiment, the ECC decoder may use, for example, a Log Likelihood Ratio Turbo Code (LLR-TC) for the soft decision decoding. A Log Likelihood Ratio (LLR) may be calculated as a non-linear function for a distance between a sampled value and an ideal value. In addition, a Turbo Code (TC) may include a simple code, for example, a Hamming code, in two or three dimensions and repeat decoding in a row direction and a column direction to improve reliability of values.

The power management unit (PMU) 140 may control electrical power provided to the controller 130. The PMU 140 may monitor the electrical power supplied to the memory system 110, e.g., a voltage supplied to the controller 130, and provide the electrical power to components included in the controller 130. The PMU 140 may not only detect power-on or power-off, but also generate a trigger signal to enable the memory system 110 to urgently back up a current state when the electrical power supplied to the memory system 110 is unstable. According to an embodiment, the PMU 140 may include a device or a component capable of accumulating electrical power that may be used in an emergency.

The memory interface (I/F) 142 may serve as an interface for handling commands and data transferred between the controller 130 and the memory device 150, in order to allow the controller 130 to control the memory device 150 in response to a command or a request input from the host 102. The memory interface 142 may generate a control signal for the memory device 150 and may process data input to, or output from, the memory device 150 under the control of the processor 134 in a case when the memory device 150 is a flash memory.

For example, when the memory device 150 includes a NAND flash memory, the memory interface 142 includes a NAND flash controller (NFC). The memory interface 142 can provide an interface for handling commands and data between the controller 130 and the memory device 150. In accordance with an embodiment, the memory interface 142 can be implemented through, or driven by, firmware called a Flash Interface Layer (FIL) for exchanging data with the memory device 150.

According to an embodiment, the memory interface 142 may support an open NAND flash interface (ONFi), a toggle mode, or the like, for data input/output with the memory device 150. For example, the ONFi may use a data path (e.g., a channel, a way, etc.) that includes at least one signal line capable of supporting bi-directional transmission and reception in a unit of 8-bit or 16-bit data. Data communication between the controller 130 and the memory device 150 can be achieved through at least one interface regarding an asynchronous single data rate (SDR), a synchronous double data rate (DDR), a toggle double data rate (DDR), or the like.

The memory 144 may be used as a working memory of the memory system 110 or the controller 130, while temporarily storing transactional data for operations performed in the memory system 110 and the controller 130. For example, the memory 144 may temporarily store read data entries output from the memory device 150 in response to a read request from the host 102 before the read data entries are output to the host 102. In addition, the controller 130 may temporarily store write data entries input from the host 102 in the memory 144 before programming the write data entries in the memory device 150. When the controller 130 controls operations, such as a data read operation, a data write or program operation, a data erase operation, etc., of the memory device 150, data transmitted between the controller 130 and the memory device 150 of the memory system 110 may be temporarily stored in the memory 144.

In addition to the read data entries or write data entries, the memory 144 may store information, e.g., map data, read requests, program requests, etc. used for inputting or outputting data between the host 102 and the memory device 150. According to an embodiment, the memory 144 may include one or more of a command queue, a program memory, a data memory, a write buffer/cache, a read buffer/cache, a data buffer/cache, a map buffer/cache, and so on. The controller 130 may allocate some storage space in the memory 144 for a component which is established to carry out a data input/output operation. For example, the write buffer established in the memory 144 may be used to temporarily store target data subject to a program operation.

In an embodiment, the memory 144 may be implemented with a volatile memory. For example, the memory 144 may be implemented with a static random access memory (SRAM), a dynamic random access memory (DRAM), or both. Although FIG. 2 illustrates, for example, the memory 144 disposed within the controller 130, embodiments are not limited thereto. The memory 144 may be located within or external to the controller 130. For instance, the memory 144 may be embodied by an external volatile memory having a memory interface transferring data and/or signals between the memory 144 and the controller 130.

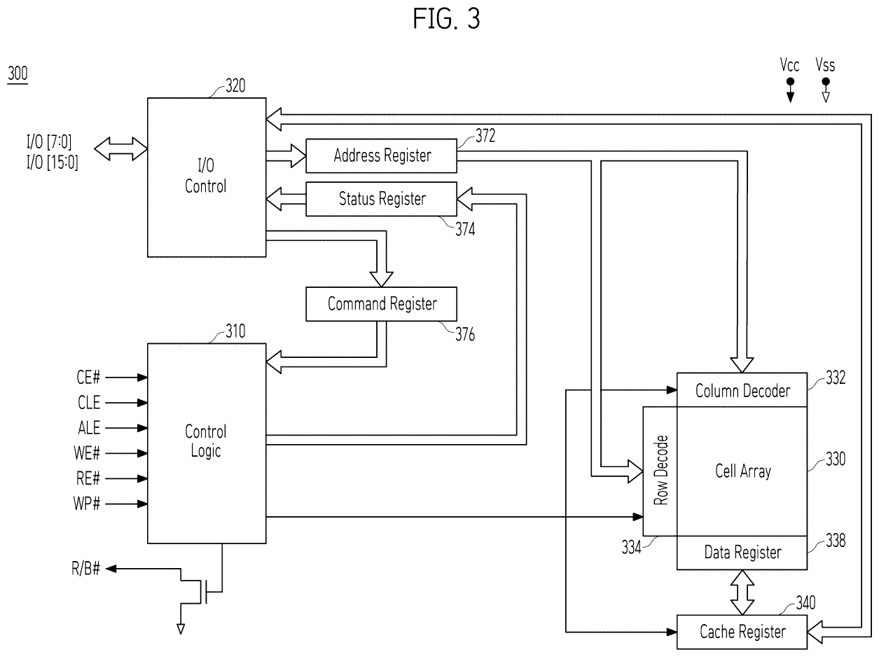

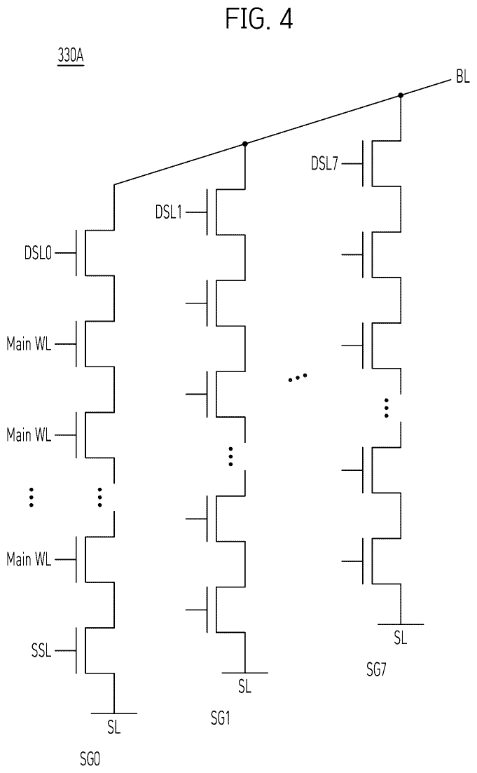

The processor 134 may control the overall operations of the memory system 110. For example, the processor 134 may control a program operation or a read operation of the memory device 150 in response to a write request or a read request entered from the host 102. According to an embodiment, the processor 134 may execute firmware to control the program operation or the read operation in the memory system 110. Herein, the firmware may be referred to as a flash translation layer (FTL). An example of the FTL will be described in detail, referring to FIGS. 3 and 4. According to an embodiment, the processor 134 may be implemented with a microprocessor, a central processing unit (CPU), or the like.

According to an embodiment, the memory system 110 may be implemented with at least one multi-core processor. The multi-core processor is a type of circuit or chip in which two or more cores, which are considered distinct processing regions, are integrated. For example, when a plurality of cores in the multi-core processor drive or execute a plurality of flash translation layers (FTLs) independently, a data input/output speed (or performance) of the memory system 110 may be improved. According to an embodiment, the data input/output (I/O) operations in the memory system 110 may be independently performed through different cores in the multi-core processor.

The processor 134 in the controller 130 may perform an operation corresponding to a request or a command input from the host 102. Further, the memory system 110 may perform an operation independent from a command or a request input from the host 102. In one case, an operation performed by the controller 130 in response to the request or the command input from the host 102 may be considered a foreground operation, while an operation performed by the controller 130 independently from the request or the command input from the host 102 may be considered a background operation. The controller 130 may perform foreground or background operations for reading, writing, or erasing data in the memory device 150. In addition, a parameter set operation corresponding to a set parameter command or a set feature command as a set command transmitted from the host 102 may be considered a foreground operation. Background operations that can be performed without a command transmitted from the host 102 by the controller 130 include garbage collection (GC), wear leveling (WL), bad block management for identifying and processing bad blocks, or the like.

According to an embodiment, substantially similar operations may be performed as both the foreground operation and the background operation. For example, when the memory system 110 performs garbage collection in response to a request or a command input from the host 102 (e.g., Manual GC), the garbage collection can be considered a foreground operation. When the memory system 110 performs garbage collection independently of the host 102 (e.g., Auto GC), the garbage collection can be considered a background operation.

When the memory device 150 includes a plurality of dies (or a plurality of chips) each including a plurality of non-volatile memory cells, the controller 130 may perform parallel processing regarding plural requests or commands input from the host 102 in order to improve performance of the memory system 110. For example, the transmitted requests or commands may be divided into plural groups including at least some of a plurality of planes, a plurality of dies, or a plurality of chips included in the memory device 150, and the plural groups of requests or commands may be processed individually or in parallel in each plane, each die or each chip. The memory interface 142 in the controller 130 may be connected to the plurality of dies or chips in the memory device 150 through at least one channel and at least one way. When the controller 130 distributes and stores data in the plurality of dies through each channel or each way in response to requests or commands associated with a plurality of pages including non-volatile memory cells, a plurality of operations corresponding to the requests or the commands can be performed simultaneously or in parallel in the plurality of dies or planes. Such a processing method or scheme can described as an interleaving method. Because a data input/output speed of the memory system 110 increases by operating with the interleaving method, data I/O performance of the memory system 110 can be improved.

By way of example but not limitation, the controller 130 may recognize statuses of a plurality of channels (or ways) associated with the plurality of dies included in the memory device 150. The controller 130 may determine a status of each channel or each connection as one of a busy status, a ready status, an active status, an idle status, a normal status, and an abnormal status. The determination of which channel or connection an instruction (and/or a data) is delivered through by the controller can be associated with a physical block address. The controller 130 may refer to descriptors delivered from the memory device 150. The descriptors may include a block or page of parameters describing something about the memory device 150. The descriptors can have a predetermined format or structure. For instance, the descriptors may include device descriptors, configuration descriptors, unit descriptors, and the like. The controller 130 may refer to, or use, the descriptors to determine which channel(s) or way(s) is used to exchange an instruction or data.

Referring to FIG. 2, the memory device 150 in the memory system 110 may include a plurality of memory blocks 152, 154, 156. Each of the plurality of memory blocks 152, 154, 156 includes a plurality of non-volatile memory cells. According to an embodiment, the memory block 152, 154, 156 can be a group of non-volatile memory cells erased together. The memory block 152, 154, 156 may include a plurality of pages which is a group of non-volatile memory cells read or programmed together.

According to an embodiment, each memory block 152, 154, or 156 may have a three-dimensional stack structure for a high integration. Further, the memory device 150 may include a plurality of dies, each die including a plurality of planes, each plane including the plurality of memory blocks 152, 154, 156. A configuration of the memory device 150 may be changed depending on performance of the memory system 110.

FIG. 2 illustrates the memory device 150 that includes the plurality of memory blocks 152, 154, and 156. The plurality of memory blocks 152, 154, and 156 may be any of single-level cell (SLC) memory blocks, multi-level cell (MLC) memory blocks, or the like, according to the number of bits that can be stored in one memory cell. An SLC memory block includes a plurality of pages implemented by memory cells, each memory cell storing one bit of data. An SLC memory block may have higher data I/O operation performance and higher durability than the MLC memory block. The MLC memory block includes a plurality of pages implemented by memory cells, each memory cell storing multi-bit data, e.g., two or more bits of data. The MLC memory block may have larger storage capacity for the same space compared to the SLC memory block. The MLC memory block can be highly integrated in a view of storage capacity.

According to an embodiment, the memory device 150 may be implemented with MLC memory blocks such as a double level cell (DLC) memory block, a triple-level cell (TLC) memory block, a quadruple-level cell (QLC) memory block, and a combination thereof. The DLC memory block may include a plurality of pages implemented by memory cells, each memory cell capable of storing 2-bit data. The TLC memory block can include a plurality of pages implemented by memory cells, each memory cell capable of storing 3-bit data. The QLC memory block may include a plurality of pages implemented by memory cells, each memory cell capable of storing 4-bit data. In another embodiment, the memory device 150 may be implemented with a block including a plurality of pages implemented by memory cells, each memory cell capable of storing five or more bits of data.

According to an embodiment, the controller 130 may use an MLC memory block included in the memory device 150 as an SLC memory block that stores one-bit data in one memory cell. A data input/output speed of the multi-level cell (MLC) memory block can be slower than that of the SLC memory block. That is, when the MLC memory block is used as the SLC memory block, a margin for a read or program operation can be reduced. For example, the controller 130 may perform a data input/output operation with a higher speed when the MLC memory block is used as the SLC memory block. Thus, the controller 130 may use the MLC memory block as a SLC buffer to temporarily store data because the buffer may require a high data input/output speed for improving performance of the memory system 110.

Further, according to an embodiment, the controller 130 can program data in an MLC a plurality of times without performing an erase operation on a specific MLC memory block included in the memory device 150. In general, non-volatile memory cells do not support data overwrite. However, the controller 130 may program 1-bit data in the MLC a plurality of times using a feature in which the MLC is capable of storing multi-bit data. For an MLC overwrite operation, the controller 130 may store the number of program times as separate operation information when 1-bit data is programmed in an MLC. According to an embodiment, an operation for uniformly levelling threshold voltages of the MLCs may be carried out before another 1-bit data is programmed in the same MLCs, each having stored 1-bit data.

According to an embodiment, the memory device 150 may be embodied as a non-volatile memory such as a flash memory, for example, a NAND flash memory, a NOR flash memory, or the like. In another embodiment, the memory device 150 may be implemented by at least one of a programmable ROM (PROM), an erasable ROM (EPROM), an electrically erasable ROM (EEPROM), a phase change RAM (PRAM), a magnetic RAM (MRAM), a Resistive RAM (RRAM) a phase change random access memory (PCRAM), a ferroelectrics random access memory (FRAM), a spin transfer torque random access memory (STT-RAM), and a spin transfer torque magnetic random access memory (STT-MRAM), or the like.

FIG. 3 illustrates a memory device 300 according to an embodiment of the present disclosure. The memory device 300 described in FIG. 3 can be understood as an example of the memory device 150 described in FIG. 2.

Referring to FIG. 3, the memory device 300 can include at least one memory die. The memory device 300 can receive or output a plurality of control signals chip enable CE #, command latch enable CLE, address latch enable ALE, write enable WE #, read enable RE #, write protect WP #, ready/busy R/B #, and receive or transmit data or operation information through channels I/O [7:0], I/O [15:0]. For example, a predetermined amount of data (e.g., 1 byte (8 bits) or 2 bytes (16 bits)) can be transmitted and received according to a channel (e.g., I/O [7:0], I/O [15:0]) connecting the memory device 300 and a controller such as the controller 130 shown in FIG. 2.

According to an embodiment, the memory device 300 may include a plurality of pins or pads. For example, the plurality of control signals CE #, CLE, ALE, WE #, RE #, WP #, R/B #can be transmitted or received through exclusively allocated pins. The control signals may include a chip enable signal CE #, a command latch enable signal CLE, an address latch enable signal ALE, a write enable signal WE #, a read enable signal RE #, a write protect signal WP #, a status signal R/B #indicating a ready state or a busy state, and the like. The control signals CE #, CLE, ALE, WE #, RE #, WP #, R/B #can be controlled (transmitted and received) by control circuitry 310 included in the memory device 300.

A control circuit 310 may perform preset operation mechanisms in response to commands and addresses input to the memory device 300. For example, when a read command is received, the control circuit 310 may manage and control components in the memory device 300 to sequentially perform operations or tasks corresponding to the read command. In addition, when the controller 130 described in FIG. 2 transmits a command to check an operation status of the memory device 300, the control circuit 310 may check information regarding the operation status and output the information to the controller 130. The control circuit 310 may be configured to perform an operation or task corresponding to a specific command or a specific interrupt according to a preset procedure in response to an input command or the interrupt, and then transmit a result of the operation or task.

The memory device 300 can include an input and output (input/output (I/O)) control circuit 320. The input/output control circuit 320 can be connected to other devices or components (e.g., a controller) through the channels I/O [7:0], I/O [15:0]. The input/output control circuit 320 in the memory device 300 can be coupled to a plurality of registers 372, 374, 376 and a cache register 340 coupled to a cell array 330.

According to an embodiment, the input/output control circuit 320 can include a chip select decoder, while the memory device 300 may include a plurality of memory chips. Chip select function may be used to activate one of the plurality of memory chips included in or connected to a memory system or a data processing system. Depending on the embodiment, the chip select decoder may be implemented with combinational logic gates that activate one specific output line in response to an input binary code. The memory system or the data processing system can use an activated output line to activate or “select” a specific chip or device from multiple devices connected to the memory system or the data processing system. For example, if there are multiple memory chips on a same bus (such as flash memory chips in solid state drives (SSDs)), for most operations it is impossible to communicate with all memory chips simultaneously because data entries or commands sent across the bus could be routed to all memory chips. Instead, a chip select signal can be used to select which chip to communicate with at any given time. The chip select decoder can manage and control data communication between multiple devices (e.g., the multiple memory chips) that share the same bus or connection lines in a system by activating one specific device based on an input select code or signal.

According to an embodiment, the memory device 300 can include the cache register 340, an address register 372, a status information register 374, and a command register 376. The cache register 340 can temporarily store data. When the memory device 300 performs a read operation, the cache register 340 can store a read data entry output from the cell array 330. When the memory device 300 performs a write operation or a program operation, the cache register 340 can store a write data entry. The address register 372 can store an address indicating a location of the cell array 330 where a read operation or a write operation is to be performed. The command register 376 can store a command to be executed by the memory device 300. The status information register 374 can store status information such as a result (failure/success) of an operation performed in the memory device 300 or readiness for performing an operation. For example, when a plurality of memory planes is included in a memory die in the memory device 300, the status information register 374 can store status information regarding each of the plurality of memory planes. Data, commands, and information transmitted or received through the input/output control circuit 320 in the memory device 300 can be controlled (e.g., transmitted, moved, or output) by the control circuitry 310.

During a read operation in the memory device 300, a row decoder 334 and a column decoder 332 can select one or more memory cells in the cell array 330 based on an address stored in the address register 372 and a control signal from the control circuitry 310. During a read operation, a read data entry output from the cell array 330 may be stored in the data register 338 and then transferred from the data register 338 to the cache register 340. The read data entry stored in the cache register 340 may be transferred to the input/output control circuit 320 through input/output lines. The read data entry transmitted to the input/output control circuit 320 may be output to the controller through the channels I/O [7:0], I/O [15:0].

During a write operation or a program operation in the memory device 300, the row decoder 334 and the column decoder 332 can select one or more memory cells in the cell array 330 in response to an address stored in the address register 372 and a control signal from the control circuitry 310. During the write operation, the write data entry transferred from the controller to the input/output control circuit 320 through the channels I/O [7:0], I/O [15:0] can be stored in the cache register 340. Thereafter, the write data entry may be transferred from the cache register 340 to the data register 338. The write data entry stored in the data register 338 can be programmed in selected memory cells in the cell array 330 by the control circuitry 310.

The data register 338 and the cache register 340 can be included in a read/write circuit comprising a sense amplifier, a page buffer, or the like. According to an embodiment, page buffers or data latches included in the memory device 300 can correspond to the data register 338 and/or the cache register 340. Further, the cache register 340 is configured to temporarily store data transmitted between the data register 338 and the input/output control circuit 320. The cache register 340 may have a pipe latch structure depending on the embodiment.

A pipeline (or pipelining) system including at least one pipe latch can include an apparatus that can parallelize a plurality of data entries input and output serially. According to an embodiment, the pipeline system is applicable to the input/output control circuit 320 or the cache register 340. Further, according to an embodiment, the pipeline system may be used to compensate for delays and noise occurring in a data transmission process as a data path through which data is transmitted within the memory device 300 of the memory system becomes longer.

The cell array 330 shown in FIG. 3 can have a two-dimensional or three-dimensional structure. Hereinafter, various structures of the cell array 330 and an operation for programming data or verifying programmed data in a plurality of memory cells included in the cell array 330 will be specifically described.

FIG. 4 illustrates a structure of a first cell array 330A according to an embodiment of the present disclosure.

Referring to FIG. 4, the first cell array 330A can include a plurality of cell strings SG0, SG1, . . . , SG7. The plurality of cell strings SG0, SG1, . . . , SG7 can be coupled to a bit line BL. The connection between each of the plurality of cell strings SG0, SG1, . . . , SG7 and the bit line BL can be determined through (each of corresponding) drain select lines DSL0, DSL1, . . . , DSL7.

Among the plurality of cell strings SG0, SG1, . . . , SG7, a first cell string SG0 can include a plurality of memory cells, each memory cell capable of storing one-bit data or multi-bit data, a switching transistor coupled to a first drain select line DSL0, and a switching transistor coupled to a source select line SSL for controlling connection to a source line SL. According to an embodiment, each switching transistor can include plural transistors.

Plural memory cells can be coupled to plural word lines Main_WL. A single memory cell can be connected to a single word line among the plural word lines Main_WL. Based on the bit line BL and one of the plural word lines Main_WL, the control circuitry 180 can select a specific memory cell in a selected cell string within the first cell array 330A.

For example, the word line Main_WL can be coupled to one memory cell included in each of the plurality of cell strings SG0, SG1, . . . , SG7. As the number of the plurality of cell strings SG0, SG1, . . . , SG7 coupled to the word line Main_WL increases, the data storage capacity of the first cell array 330A can increase. Due to a delay (e.g., RC delay, etc.), voltages of various levels transmitted through the word line Main_WL can reach the first cell string SG0 and the eighth cell string SG7 at different times. As the number of the plurality of cell strings SG0, SG1, . . . , SG7 coupled to the word line Main_WL increases, the times at which the voltage is applied to a cell string (e.g., the first cell string SG0) closest to the voltage supply circuit 170 and a cell string (e.g., the eighth cell string SG7) farthest from the voltage supply circuit 170 can differ more significantly. According to an embodiment of the present disclosure, a memory device and an operating method of the memory device capable of avoiding or resolving an issue caused based on a phenomenon that the times differ at which the voltage is applied to each of the plurality of cell strings SG0, SG1, . . . , SG7 coupled to the word line Main_WL will be described below.

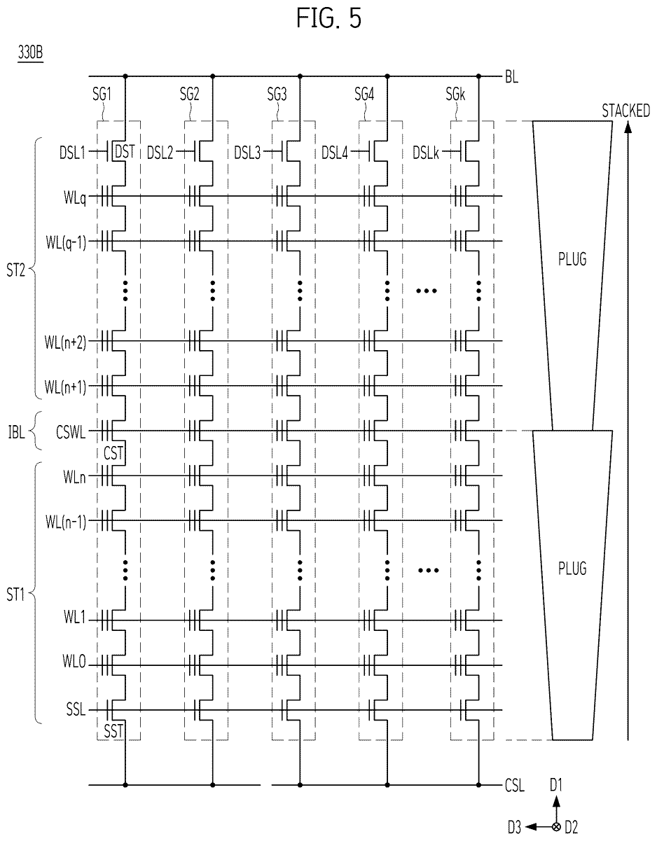

FIG. 5 illustrates a structure of a second cell array 330B according to an embodiment of the present disclosure.

Referring to FIG. 5, the second cell array 330B can have a structure including portions or layers stacked in a vertical direction D1. The second cell array 330B can include at least one memory block. Hereinafter, a direction substantially perpendicular to the upper surface of the substrate may be defined as a first direction D1, and two directions parallel to the upper surface of the substrate and intersecting each other may be defined as the second direction D2 and the third direction D3, individually. For example, the second direction D2 and the third direction D3 may intersect each other substantially perpendicularly. The first direction D1 may be referred to as a vertical direction, the second direction D2 may be referred to as a row direction, and the third direction D3 may be referred to as a column direction. The direction indicated by the arrow in the drawing and the direction opposite to it are described as the same direction.

For convenience of description, FIG. 5 shows NAND strings or cell strings SG1 to SGk connected to one bit line BL and one common source line CSL among the cell strings included in the memory block.

The memory block may include a plurality of cell strings SG1 to SGk connected between the same bit line (BL) and the common source line CSL. Each of the cell strings SG1 to SGk can include at least one source select transistor SST controlled by a source select line SSL, plural memory cells controlled by word lines WL (shown as WL0, WL1, WL(n−1), WLn, WL(n+1), WL(n+2), WL(q−1), and WLq), a central switching transistor CST disposed in an intermediate boundary layer IBL and controlled by a central switching word line CSWL, and a drain select transistor DST controlled by each drain select line DSL1, DSL2, DSL3, . . . , DSLK.

According to an embodiment, plural memory cells connected to at least one word line located at both ends of first and second stacks ST1, ST2 in the first direction D1 may be dummy cells. Any data may not be stored in the dummy cells. Further, according to an embodiment, the dummy cells may be used to store data having a smaller number of bits than other memory cells. According to an embodiment, the intermediate boundary layer IBL may include at least one gate line. One gate line corresponds to the central switching word line CSWL which can simultaneously control switching operations of the central switching transistors CST connected thereto. Although FIG. 5 illustrates a structure in which the first and second stacks ST1, ST2 are stacked, three or more stacks may be vertically stacked in the second cell array 330B. When a plurality of stacks are stacked, an intermediate boundary layer IBL may be formed and disposed between each two stacked stacks. The intermediate boundary layer IBL may include at least one switching transistor configured to couple memory cells in one stack of the two stacks to other memory cells in the other stack.

FIG. 5 shows an embodiment in which the source select transistors SST included in the plurality of cell strings SG1 to SGk are connected to the common select line CSL. However, according to an embodiment, a certain (for example, predetermined) number of source select transistors may be coupled to each of plural source ground select lines.

Referring to FIGS. 4 to 5, the first or second cell array 330A, 330B can include a plurality of memory blocks arranged along a plurality of directions D1, D2, D3. In an embodiment, a memory block may be selected by the control circuit 310 included in the memory device 300 shown in FIG. 3. For example, a read voltage, a program voltage, or an erase voltage may be applied to a memory block and a word line selected by the control circuit 310.

Each of the cell strings SG1 to SGk may include a plurality of switch transistors as well as a plurality of memory cells capable of storing data. Here, the plurality of switch transistors can include a drain select transistor DST, a source select transistor SST, and a central switching transistor CST. FIG. 5 shows an embodiment in which each of the cell strings SG1 to SGK includes one drain select transistor DST, one source select transistor SST, and one central switching transistor CST, respectively. However, according to an embodiment, each of the cell strings SG1 to SGk may include a plurality of drain select transistors DST, a plurality of source select transistors SST, or a plurality of intermediate switching transistors CST.

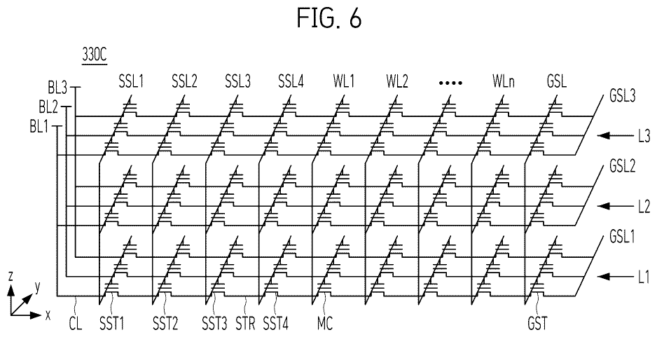

FIG. 6 illustrates a structure of a third cell array 330C according to an embodiment of the present disclosure.

Referring to FIGS. 5 and 6, the third cell array 330C may be stacked in the vertical direction (D1, Z) through a plurality of stacks ST1, ST2, as described in FIG. 5, and non-volatile memory cells can be placed in three-dimensional (3D) space. Specifically, FIG. 6 illustrates the third cell array 330C in a 3D non-volatile memory device according to an embodiment of the present disclosure.

The third cell array 330C may include a plurality of memory cells MC arranged in a cell string STR in a plurality of memory layers (e.g., three memory layers L1, L2, L3). The memory layers L1, L2, L3 may be respectively connected to a plurality of bit lines BL1, BL2, BL3 through a first end of the plurality of channel lines CL and to the common source line CSL through a second end of the plurality of channel lines CL. The third cell array 330C may include a plurality of source select lines SSL1 to SSL4 connected to source select transistors SST1 to SST4. In addition, a plurality of word lines WL1 to WLn and a ground select line GSL (illustrated as, respectively, GSL1, GSL2, GSL3) may be connected to each of the memory layers L1, L2, L3. The plurality of source select lines SSL1 to SSL4, the plurality of word lines WL1 to WLn, and the ground select line GSL may be arranged in a direction that intersects a plurality of channel lines CL. Each of the plurality of channel lines may be described as the cell string STR. Each of the cell strings STR may include the source select transistors SST1 to SST4 respectively connected to the plurality of source select lines SSL1 to SSL4. The ground select line GSL may be grounded to turn off the ground selection transistor GST.

The plurality of word lines WL1 to WLn may each be connected to control gates of memory cells arranged in a column direction. Each of the plurality of bit lines BL1 to BL3 may be connected to one end of the source select transistors. A plurality of memory cells having control gate electrodes connected to each word line WL1 to WLn in the row direction can configure a page, which is a unit for storing data or a data entry. The number of pages could be changed or determined depending on a storage capacity of the memory cells.

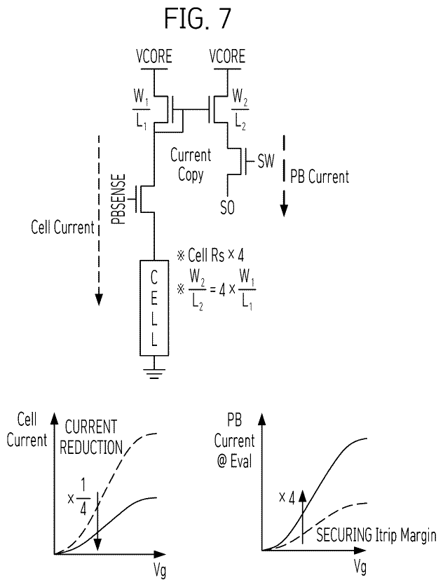

FIG. 7 illustrates a memory device according to an embodiment of the present disclosure.

Referring to FIG. 1 and FIG. 7, the memory device can form different current paths in the memory cell 346 and the page buffer 348. A cell current (e.g., Cell Current) can flow through the memory cell 346, and a page buffer current (e.g., PB Current) can flow in the page buffer 248. The memory device can include a current mirror between the memory cell 346 and the page buffer 348.

FIG. 7 illustrates a case where the current gain is 4 times so that the page buffer current (e.g., PB Current) can be compensated for a reduction rate (i.e., ¼) of the cell current (e.g., Cell Current). By generating the page buffer current (e.g., PB Current) in the evaluation period (approximately up to 600 ns) during the read process, the size of the consumption current (Icc) representing the current consumption in the NAND flash memory could be reduced. The current gain (A) of the current mirror can be defined as follows.

$$A = \frac{{I}_{out}}{{I}_{in}} \\ ( {I}_{out} : output current , {I}_{in} : input current )$$

The widths (W) and lengths (L) of the channels of the transistors constituting the current mirror can affect the current gain. For example, the larger the width/length (W/L) ratio of the transistor, the greater the current flow capability of the transistor. When the width/length (W/L) ratios of the input transistor and the output transistor included in the current mirror are different, the output current might not be the same as the input current. When the width/length (W₂/L₂) ratio of the output transistor is larger than the width/length (W₁/L₁) ratio of the input transistor, the output current could be larger than the input current as follows.

$$\frac{{W}_{2}}{{L}_{2}} = 4 \times \frac{{W}_{1}}{{L}_{1}}$$

The current mirror described in FIG. 7 can generate the page buffer current (e.g., PB Current) that is four times the cell current (e.g., Cell Current), so that the page buffer 348 can secure an operating margin due to the increased page buffer current (e.g., PB Current).

Herein, the current mirror is a circuit for creating or generating a constant current source, and has a function of outputting an arbitrary input current or reference current 1 to 1 or 1 to N times. The performance of the current mirror can be determined by a current output terminal with infinite impedance, a current up-conversion terminal with zero impedance, and an ability/capability to replicate current 1 to 1 and amplify arbitrary current. The current mirror described in FIG. 7 can have a high input impedance and a low output impedance, and therefore may have a disadvantage in that it may not be capable of performing high-precision current replication and amplification. According to an embodiment, the memory device can include a Wilson current mirror and a regulated cascade current mirror to increase the output impedance.

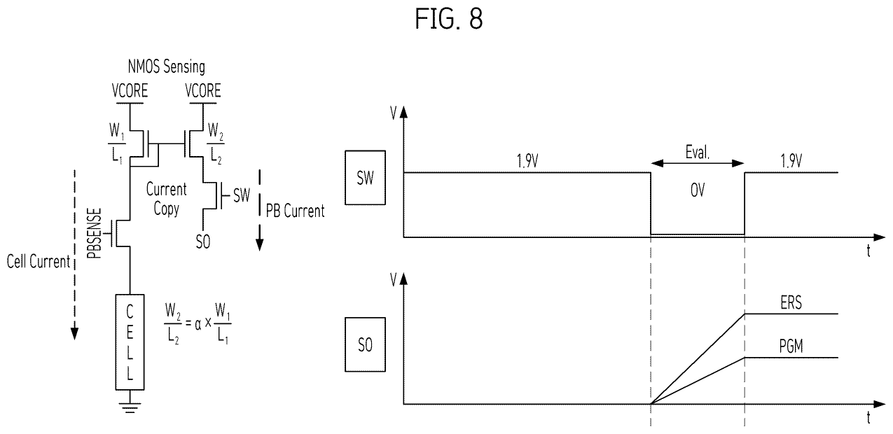

FIG. 8 illustrates a memory device according to an embodiment of the present disclosure. FIG. 8 illustrates one example of the current mirror described in FIG. 7.

Referring to FIG. 8, the current mirror can include two P-channel metal-oxide-semiconductor (PMOS) transistors having one side connected to a power supply voltage VCORE. The current gain of the current mirror can be (the value) “α”. For example, the gain may be expressed as

$$\frac{W 2}{L 2} = α \times \frac{W 1}{L 1} ,$$

similarly as described with respect to the current mirror of FIG. 7.

The page buffer current (e.g., PB Current) copied through the current mirror can be generated only in the evaluation period (Eval.). At this time, the switch SW located on the output side of the current mirror can be turned on, and the page buffer current (e.g., PB Current) can flow in the sensing line SO. The switch SW can be turned off before the evaluation period (Eval.), e.g., a precharge period, and after the evaluation period (Eval.), e.g., a sensing period. After the evaluation section (Eval.), the sensing line SO can be kept in a floating state at its potential because the connection between the current mirror and the sensing line SO is electrically cut off.

The potential of the sensing line SO can be different during an erase operation and a program operation. Due to the current mirror including two PMOS transistors having one side connected to the power supply voltage VCORE, the potential (ERS) of the sensing line SO during the erase operation could be higher than the potential (PGM) of the sensing line SO during the program operation.

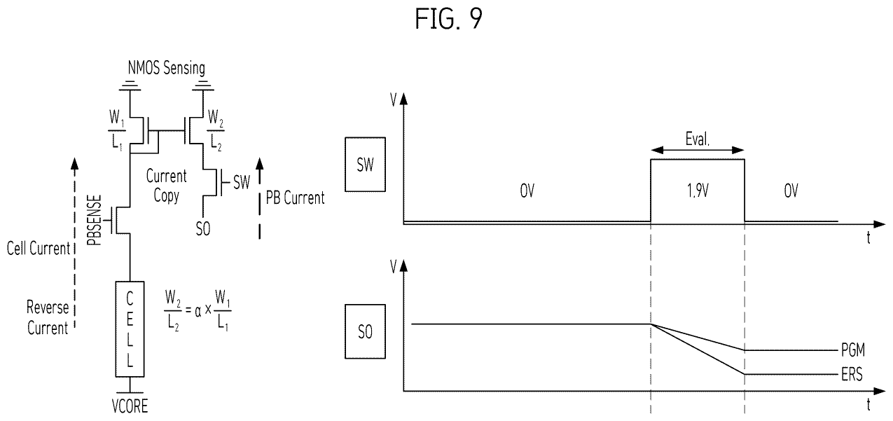

FIG. 9 illustrates a memory device according to an embodiment of the present disclosure. FIG. 9 illustrates one example of the current mirror described in FIG. 7.

Referring to FIG. 9, the current mirror can include two N-channel metal-oxide-semiconductor (NMOS) transistors having on side connected a ground voltage GND. The current gain of the current mirror can be the value “α”, which may be a whole number or any number greater than 1.

The page buffer current (e.g., PB Current) copied through the current mirror can be generated only in the evaluation period (Eval.). During this period, the switch SW located on the output side of the current mirror may be turned on, and the page buffer current (e.g., PB Current) may flow through the sensing line SO. The switch SW may be turned off before the evaluation period (Eval.), e.g., the precharge period, and after the evaluation period (Eval.), e.g., the sensing period. After the evaluation section (Eval.), the sensing line SO can be maintained in a floating state because the connection between the current mirror and the sensing line SO is electrically cut off.

The sensing line SO may have different potentials during the erase operation and the program operation. Due to the current mirror including two NMOS transistors having one side connected to the ground voltage GND, the potential (ERS) of the sensing line SO during the erase operation can be lower than the potential (PGM) of the sensing line SO during the program operation.

Further, when the memory device includes a current mirror including two NMOS transistors having one side connected to the ground voltage GND, the memory device may have an advantage of reducing a consumption current (Icc) compared to the current mirror including two PMOS transistors having one side connected to the power supply voltage VCORE.

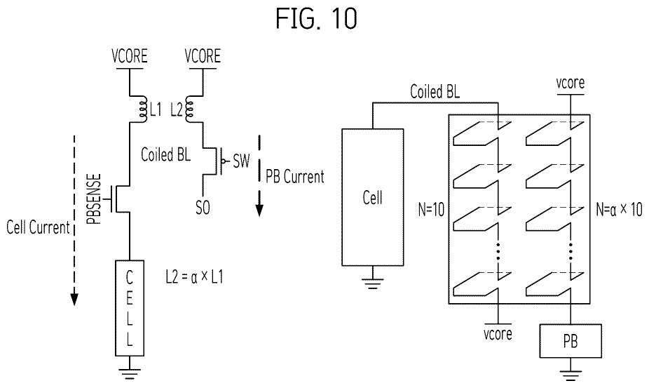

FIG. 10 illustrates a memory device according to an embodiment of the present disclosure. FIG. 10 illustrates one example of the current mirror described in FIG. 7.

Referring to FIG. 10, the current mirror can include two inductors L1, L2 connected to one side of a power supply voltage VCORE. The current gain of the current mirror can be the value “α”. The inductors L1, L2 may be components that form a magnetic field when current flows and have the property of resisting changes in current. The inductors L1, L2 may be implemented in the form of a wire in which at least a part of a bit line BL connected to a memory cell and a sensing line SO connected to a page buffer are wound in a coil shape. When the current mirror uses an inductor, there is no need to additionally place a transistor in the memory device.

The page buffer current (e.g., PB Current) copied through the current mirror can be generated only in the evaluation section (Eval.). During this period, the switch SW located on the output side of the current mirror is turned on, and the page buffer current (e.g., PB Current) can flow through the sensing line SO. The switch SW can be turned off before the evaluation period (Eval.), e.g., the precharge period, and after the evaluation period (Eval.), e.g., the sensing period. After the evaluation period (Eval.), the sensing line SO can be maintained in a floating state with a potential because the connection between the current mirror and the sensing line SO is electrically cut off.

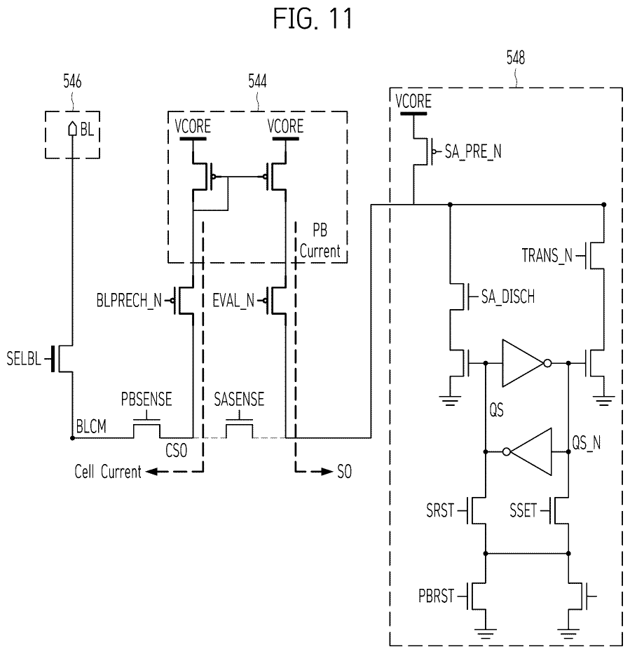

FIG. 11 illustrates a memory device according to an embodiment of the present disclosure.

Referring to FIG. 11, the memory device can include a current mirror 544 between a memory cell region 546 and a page buffer 548. The current mirror 544 can generate a page buffer current (e.g., PB Current) flowing through the page buffer 548 in response to a cell current (e.g., Cell Current) flowing through a bit line BL. As described in FIGS. 7 to 10, the current mirror 544 may have a preset current gain.

According to an embodiment, the current mirror 544 may have different current gains and operation times during a read operation and a program operation for at least one memory cell. In addition, the current gain of the current mirror 544 can be determined during a post-manufacturing test process.

According to an embodiment, the memory device may further include a switching element that directly connects the input side and the output side of the current buffer 544. The switching element can be turned on or off in response to the detection control signal SASENSE. For example, during a read operation, the memory device can turn off the switching element and generate a page buffer current (e.g., PB Current) through the current mirror 544. On the other hand, during a write operation, the memory device can turn on the switching element and electrically disconnect the connection of the current mirror 544. Meanwhile, according to an embodiment, the operation of the switching element can be determined through a post-manufacturing test process. In addition, according to an embodiment, the current gain of the current mirror 544 can be made different during a read operation and a program operation for at least one memory cell, or a connection time between the current mirror 544 and the memory cell area 546 or the page buffer 548 may be made different.

In addition, according to an embodiment of the present disclosure, the current gain of the current mirror can vary depending on the wear degree of at least one memory cell in the memory cell area 546.

Hereinafter, the operation and configuration of the memory device will be described with a focus on the read operation.

A plurality of memory cells in the memory cell area 546 may be connected to the bit line BL. At least one of the plurality of bit lines can be selected by a bit line selection signal SELBL.

The memory device connects the bit line BL to the current mirror 544 through the page buffer detection signal PBSENSE. According to an embodiment, a switching element operated by the detection control signal SASENSE can be turned off during a read operation.

In a conventional memory device, the bit line BL is directly connected to the sensing line SO through the page buffer detection signal PBSENSE. However, the bit line BL and the sensing line SO in the memory device according to an embodiment of the present disclosure can be indirectly connected through the current mirror 544. The memory device can have different and distinguishable current paths in the bit line BL and the sensing line SO.

In response to a precharge signal BLPRECH_N, the memory device can precharge the bit line BL. After the bit line BL is precharged to a preset level based on the precharge signal BLPRECH_N, the cell current (e.g., Cell Current) can be determined when a read voltage is applied to a memory cell in the memory cell area 546.

The sensing line SO can be precharged to a preset level in response to a detection precharge signal SA_PRE_N.

In response to an evaluation signal EVAL_N, the memory device can connect the current mirror 544 to the sensing line SO. In response to the evaluation signal EVAL_N, the page buffer current (e.g., PB Current) generated in the current mirror 544 can flow through the sensing line SO.

The page buffer 548 can transfer a potential of the sensing line SO to a latch internally in response to a detection discharge signal SA_DISCH.

The page buffer 548 can include a latch structure capable of storing data in two nodes QS, QS_N. During a read operation, a binary value determined by detecting a page buffer current (i.e., PB Current) can be stored in the two nodes QS, QS_N in the page buffer 548. The two nodes QS, QS_N in the page buffer 548 can be initialized through a page buffer reset signal PBRST, a set signal SSET, and a reset signal SRST before storing data and after outputting the data. The data temporarily stored in the two nodes QS, QS_N in the page buffer 548 can be transferred to another component (e.g., a cache register 340, an input/output control circuit 320, shown in FIG. 3) in the memory device in response to a data output signal TRANS_N.

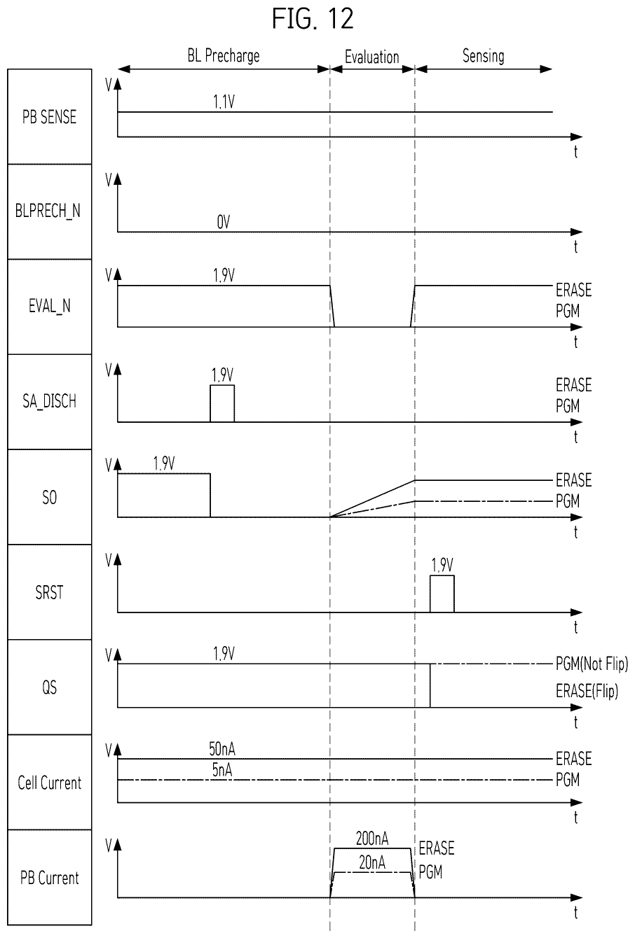

FIG. 12 illustrates an operation of the memory device described in FIG. 11. Specifically, FIG. 12 describes the read operation using the current mirror 544 in the memory device described in FIG. 11.

Referring to FIG. 12, the memory cell can have one of the erase state (ERASE) and the program state (PGM). According to an embodiment, the memory cell can store multi-bit data. However, for the convenience of explanation, the memory cell having only the two cases of the erase state (ERASE) and the program state (PGM) are described as an example.

The read operation can include a bit line precharge period (BL Precharge), an evaluation period (Evaluation), and a sensing period (Sensing). According to an embodiment, the evaluation period (Evaluation) during the read operation can be set as an initial period of the sensing period (Sensing).

Referring to FIGS. 11 and 12, when the page buffer detection signal PBSENSE and the precharge signal BLPRECH_N can be applied during a read operation, the bit line BL and the current mirror 544 can be connected. When a read voltage and a pass voltage, etc. are applied through a plurality of word lines connected to a plurality of memory cells in a memory cell area 546, a cell current (e.g., Cell Current) can flow from the current mirror 544 to the memory cell area 546. For example, when a memory cell to which a read voltage is applied in the memory cell area 546 is in an erase state (ERASE), the cell current (e.g., Cell Current) can flow at about 50 nA. On the other hand, when a memory cell to which a read voltage is applied in the memory cell area 546 is in a program state (PGM), a cell current (e.g., Cell Current) can flow at about 5 nA.

The current mirror 544 can generate a page buffer current (e.g., PB Current) that is four times the cell current (e.g., Cell Current) in response to a preset current gain (e.g., four times). For example, when a memory cell to which a read voltage is applied in the memory cell area 546 is in an erase state (ERASE), the page buffer current (e.g., PB Current) of 200 nA can be generated in response to the cell current (e.g., Cell Current) of 50 nA. On the other hand, when a memory cell to which a read voltage is applied in the memory cell area 546 is in a program state (PGM), the page buffer current (e.g., PB Current) of 20 nA can be generated in response to the cell current (e.g., Cell Current) of 5 nA.

The evaluation signal EVAL_N can be activated during the evaluation period (Evaluation) between the bit line precharge period (BL Precharge) and the sensing period (Sensing). The potential of the sensing line SO can rise by the page buffer current (e.g., PB Current) generated by the current mirror 544. The potential of the sensing line SO can rise in response to the page buffer current (e.g., PB Current) of 200 nA when the memory cell to which the read voltage is applied in the memory cell area 546 is in the erase state (ERASE). On the other hand, the potential can rise in response to the page buffer current (e.g., PB Current) of 20 nA when the memory cell to which the read voltage is applied in the memory cell area 546 is in the program state (PGM). The potential of the sensing line SO can be distinguishable in response to an amount of the page buffer current (e.g., PB Current).

The page buffer 548 can be initialized by a detection discharge signal SA_DISCH and a reset signal SRST. The page buffer 548 can sense data in response to the potential of the sensing line SO. The node (QS) in the page buffer 548 can be initialized to a logical high level (e.g., 1.9 V). In the sensing period (Sensing) after the evaluation period (Evaluation), a determination whether the node (QS) in the page buffer 548 flips in response to the potential of the sensing line SO is made. For example, when a memory cell to which a read voltage is applied in the memory cell area 546 is in an erase state (ERASE), the node (QS) in the page buffer 548 can flip. On the other hand, when a memory cell to which a read voltage is applied in the memory cell area 546 is in a program state (PGM), the node (QS) in the page buffer 548 might not flip.

As described above, as the cell array 330 in the memory device 150 becomes more highly integrated and the number of layers in the stack increases, the cell current can decrease. Issues such as a lack of sensing margin or deterioration of distribution can occur due to the decrease in the cell current. In order to avoid or prevent the decrease in the cell current, the problem due to the decrease in the cell current can be solved by generating a page buffer current (e.g., PB Current) that increases the cell current by N times (where N is a positive number greater than 1) using the current mirror 544.

As above described, a memory device or a memory system according to an embodiment of the present disclosure can reduce a phenomenon of distribution deterioration or lack of sensing margin during a read operation due to a decrease in cell current within a high-density memory device, thereby improving the data input/output performance of the memory device or the memory system.

A memory device or a memory system according to an embodiment of the present disclosure can have an advantage of improving the read performance of the memory device or the memory system by increasing an amount of the current flowing on the memory cell and the bit line by N (where N is a positive number greater than 1) times through a current mirror, thereby allowing a page buffer linked to the memory cell to easily detect the current flowing on the memory cell and the bit line.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described in detail, the code or instructions for implementing the operations of the method embodiments, may transform the computer, processor, controller, or other signal processing device into a special-purpose processor for performing the methods herein.

Also, another embodiment may include a computer-readable medium, e.g., a non-transitory computer-readable medium, for storing the code or instructions described above. The computer-readable medium may be a volatile or non-volatile memory or other storage device, which may be removably or fixedly coupled to the computer, processor, controller, or other signal processing device which is to execute the code or instructions for performing the method embodiments or operations of the apparatus embodiments herein.

The controllers, processors, control circuitry, devices, modules, units, multiplexers, logic, interfaces, decoders, drivers, generators and other signal generating and signal processing features of the embodiments disclosed herein may be implemented, for example, in non-transitory logic that may include hardware, software, or both. When implemented at least partially in hardware, the controllers, processors, control circuitry, devices, modules, units, multiplexers, logic, interfaces, decoders, drivers, generators and other signal generating and signal processing features may be, for example, any of a variety of integrated circuits including but not limited to an application-specific integrated circuit, a field-programmable gate array, a combination of logic gates, a system-on-chip, a microprocessor, or another type of processing or control circuit.

When implemented at least partially in software, the controllers, processors, control circuitry, devices, modules, units, multiplexers, logic, interfaces, decoders, drivers, generators and other signal generating and signal processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods (or operations of the computer, processor, microprocessor, controller, or other signal processing device) are described in detail, the code or instructions for implementing the operations of the method embodiments, may transform the computer, processor, controller, or other signal processing device into a special-purpose processor for performing the methods described herein.

While the present teachings have been illustrated and described with respect to specific embodiments, it will be apparent to those skilled in the art in light of the present disclosure that various changes and modifications may be made without departing from the spirit and scope of the disclosure as defined in the following claims. Furthermore, the embodiments may be combined to form additional embodiments.

What is claimed is:

1. A memory device comprising:
at least one memory cell configured to store at least one bit of data;
at least one page buffer configured to store data read from the at least one memory cell; and
a current mirror arranged between the at least one memory cell and the at least one page buffer, the current mirror having a current gain which is adaptively adjustable or controllable.

2. The memory device according to claim 1, further comprising:
a word line connected to the at least one memory cell;
a bit line connected to the at least one memory cell; and
a sensing line connected to the at least one page buffer,
wherein the current mirror is configured to connect the bit line to the sensing line, and the current gain is greater than 1.

3. The memory device according to claim 2,
wherein an operation for reading data stored in the at least one memory cell comprises a precharge period, an evaluation period, and a sensing period, and
wherein the current mirror is configured to generate, during the evaluation period, an amount of a second current flowing through the sensing line greater than an amount of a first current flowing through the bit line.

4. The memory device according to claim 3,
wherein the at least one memory cell is configured to store multi-bit data, and
wherein the first current flowing through the at least one memory cell and the bit line is determined in response to one of plural levels of a read voltage supplied through the word line.

5. The memory device according to claim 3, wherein the at least one page buffer is configured to store a binary value that is determined based on whether the second current is detected.

6. The memory device according to claim 1, wherein either a) the current gain of the current mirror has different values during a read operation and a program operation, or b) a connection time between the at least one memory cell and the at least one page buffer varies during the read operation and the program operation.

7. The memory device according to claim 1, wherein the current gain of the current mirror is determined during a test process performed after manufacturing of the memory device.

8. The memory device according to claim 1, wherein the current gain of the current mirror varies depending on a wear degree of the at least one memory cell.

9. The memory device according to claim 1, wherein the current mirror comprises P-channel metal-oxide-semiconductor (PMOS) transistors each having one side connected to a power supply voltage.

10. The memory device according to claim 1, wherein the current mirror comprises N-channel metal-oxide-semiconductor (NMOS) transistors each having one side connected to a ground voltage.

11. The memory device according to claim 1, wherein the current mirror comprises inductors each having one side connected to a power supply voltage.

12. A non-volatile memory device comprising:
a cell string including a plurality of memory cells connected in series;
a bit line connected to the cell string;
a current mirror connected to the bit line; and
at least one page buffer connected to the current mirror.

13. The non-volatile memory device according to claim 12, wherein an amount of current flowing through the cell string and the bit line is determined when voltages of different levels are applied through a plurality of word lines respectively connected to each of the plurality of memory cells, and
wherein the current mirror is configured to increase the current by N times, and flow the increased current to the at least one page buffer, N being a positive number greater than 1.

14. The non-volatile memory device of claim 13, wherein the at least one page buffer is configured to store a binary value that is determined based on whether the increased current output from the current mirror is detected.

15. The non-volatile memory device according to claim 12, wherein the current mirror comprises PMOS transistors each having one side connected to a power supply voltage.

16. The non-volatile memory device according to claim 12, wherein the current mirror comprises NMOS transistors each having one side connected to a ground voltage.

17. The non-volatile memory device according to claim 12, wherein the current mirror comprises inductors each having one side connected to a power supply voltage.

18. The non-volatile memory device according to claim 12, wherein the bit line and the at least one page buffer are not directly electrically connected.

19. A method for operating a memory device, the method comprising:
applying a read voltage to a word line connected to a memory cell;
precharging a sensing line connected to a page buffer;
operating a current mirror to increase an amount of a current, flowing through a bit line connected to the memory cell, by N times and flow the increased current to the precharged sensing line, N being a positive number greater than 1; and
storing, in the page buffer, a binary value that is determined based on whether the current flowed to the sensing line by the current mirror is detected.

20. The method according to claim 19, wherein the binary value is stored in the page buffer after the current mirror is disconnected from the sensing line.
